(19) United States
(12) Patent Application Publication
(10) Pub. No.: US 2010/0226074 A1
(43) Pub. Date: Sep. 9, 2010

(54) Display device

(75) Inventors: Ming-Chih Huang, Taichung (TW); Chien-Wei Yang, Taichung (TW)

Correspondence Address: CHARLES E. BAXLEY, ESQUIRE, 90 JOHN STREET, SUITE 309, NEW YORK, NY, 10038, US

(73) Assignee: Hiwin Mikrosystem Corp.

(21) Appl. No.: 12/380,798

(22) Filed: Mar. 4, 2009

(51) Int. Cl. H05K 7/00

(52) U.S. Cl. 361/679.01

(57) ABSTRACT

A display device is equipped with a fixing unit so that the display device can be firmly fastened to a machine housing. When the fixing unit is firmly fastened to the machine housing, a front side of the display device is level with an outer surface of the machine housing.

### BACKGROUND OF THE INVENTION

1. Technical Field

The present invention relates to a display device, and more particularly, to a display device configured to be firmly attached to a machine.

2. Description of Related Art

Referring to FIG. 1, a housing 20 of a machine typically serves to enclose internal components of the machine and a display 30 is assembled to the housing 20 for exhibiting various information or data related to operation of the machine. The display 30 received in an assembling hole 21 formed through the housing 20 may have its front provided with a flange that slightly juts out of laterals of the display 30 so that the display 30 can be inserted into the assembling hole 21 of the housing 20 with its flange abutting on edge of the assembling hole 21. However, since such a conventional display 30 comprises no mechanism helping it to be firmly combined with the housing 20, after a period of use, the display 30 tends to come off from the housing 20 under mechanical vibratility during operation of the machine. Besides, the flange designed to hold the display 30 with respect to the assembling hole 21 of the housing 20 for a determined depth is necessarily raised from the surface of housing 20. Both of the above problems not only adversely affect the appearance of the machine in esthetics, but also tend to cause the display 30 being impacted or dragged by external objects or operators of the machine, resulting in falling of the display 30 or danger to the operators.

### SUMMARY OF THE INVENTION

In view of the shortcomings of the prior art, the present invention provides a display device, which is equipped with a fixing unit to be firmly fastened to a machine housing, wherein when the fixing unit is firmly fastened to the housing, the display device has a front side being level with an outer surface of the machine housing.

The disclosed display device comprises:
a display unit for displaying, inputting and outputting data; and
a back panel having at least one fixing unit, wherein the back panel covers a rear of the display unit and the fixing unit extends outward from the back panel.

According to the present invention, the back panel and the fixing unit are formed integrally and this facilitates reducing manufacturing costs and enhancing supporting strength.

### BRIEF DESCRIPTION OF THE DRAWINGS

The invention as well as a preferred mode of use, further objectives and advantages thereof will be best understood by reference to the following detailed description of an illustrative embodiment when read in conjunction with the accompanying drawings, wherein:

FIG. 1 is a schematic drawing showing a conventional display device to be assembled to a machine housing;

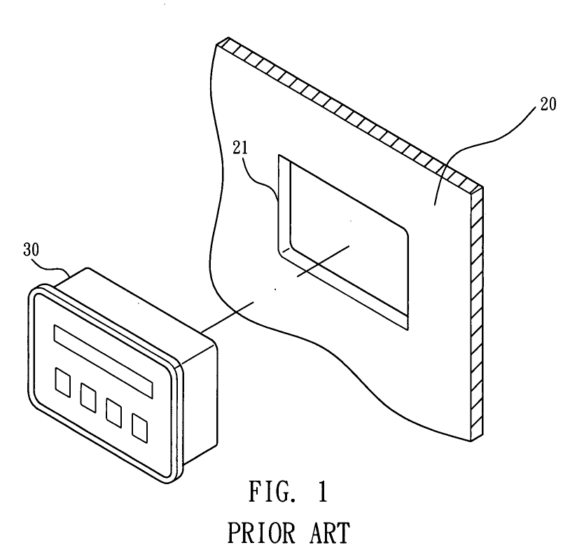

FIG. 2 is a perspective view of a back panel of the present invention, wherein the back panel is expanded;

FIG. 3 is a perspective view of the back panel of the present invention, wherein the back panel is folded;

FIG. 4 is a schematic drawing showing the display device of the present invention to be assembled to a machine housing; and

FIG. 5 is a sectional view of the display device assembled with the housing.

### DETAILED DESCRIPTION OF THE PREFERRED EMBODIMENTS

While a preferred embodiment is provided herein for illustrating the concept of the present invention as described above, it is to be understood that the components in these drawings are made for better explanation and need not to be made in scale. Moreover, in the following description, resemble components are indicated by the same numerals.

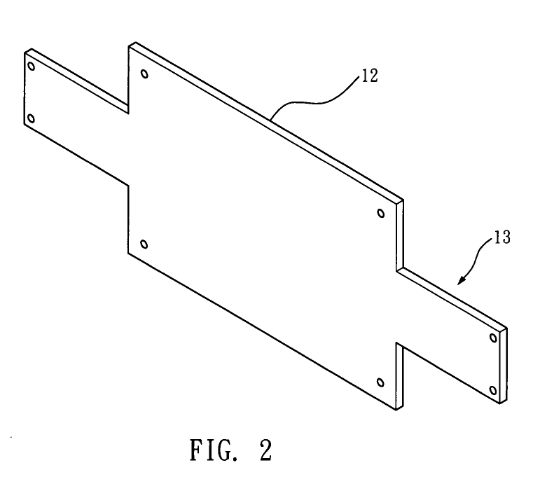

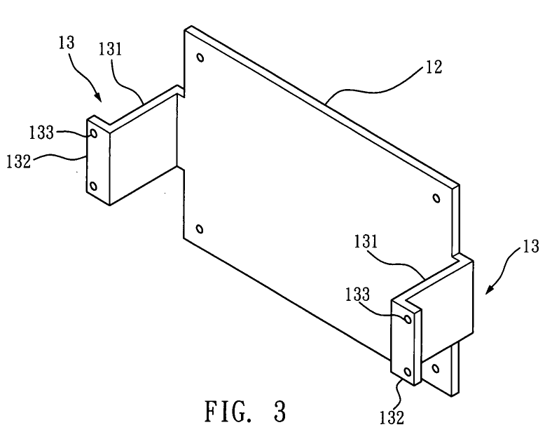

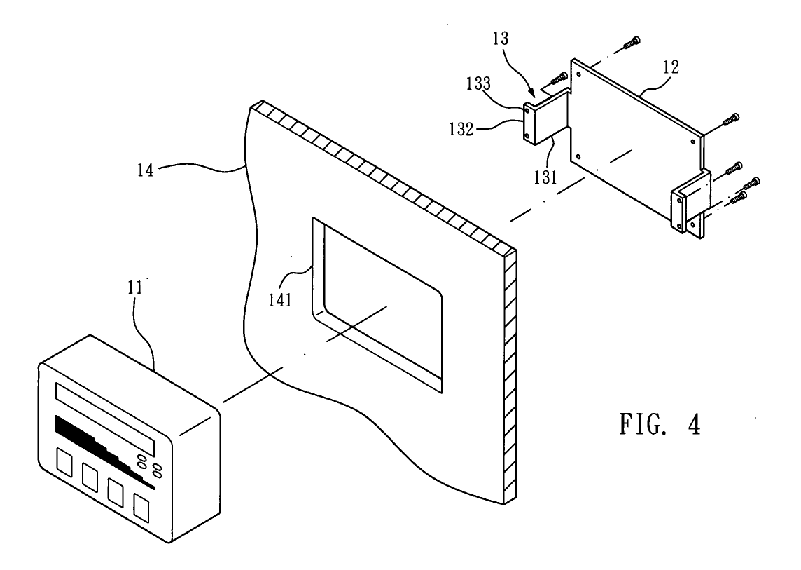

Referring to FIGS. 2 through 4, a display device comprises a display unit 11 for displaying, inputting and outputting data, and a back panel 12 having at least one fixing unit 13. The back panel 12 covers a rear side of the display unit 11 in any of known manners. The back panel 12 and the fixing unit 13 are formed integrally while the fixing unit 13 extends outward from the back panel 12. The fixing unit 13 has a first bent portion 131 to be positioned perpendicular to the back panel 12 at a border between the back panel 12 and the fixing unit 13. Furthermore, the fixing unit 13 has a second bent portion 131 extended outward at a position adjacent to a front side of the display unit 11 and the second bent portion 131 is formed with a fastening hole 133. The fastening hole 133 allows a screw to pass through so as to fix the fixing unit 13 of the back panel 12 to an inner surface of a machine housing 14. The machine housing 14 comprises an assembling hole 141 for receiving the display unit 11 and then the display unit 11 and the back panel 12 are combined by screws.

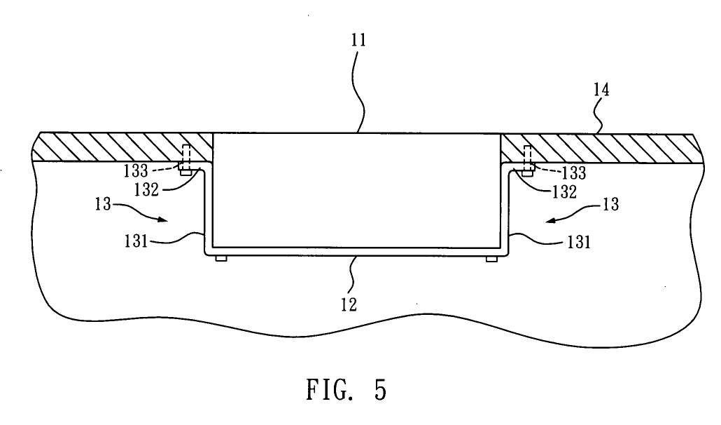

Referring to FIG. 5, by the above design, the fixing unit 13 of the back panel 12 can be firmly fixed to the inner surface of the machine housing 14. Then the display unit 11 and the back panel 12 can be firmly combined by screws. As shown in FIG. 5, since the display unit 11 is fully set in the assembling hole 141 of the machine housing 14, a front side of the display unit 11 is level with the outer surface of the housing without any jutting part. Thereby, the concern of accidents related to the prior art where the display may be impacted or dragged by external objects or operators of the machine can be eliminated while the appearance of the machine is streamlined. Besides, since the back panel 12 and the fixing unit 13 can be integrally formed through a known, economic pressing process, the manufacturing costs of the display can be reduced.

The present invention has been described with reference to the preferred embodiment and it is understood that the embodiment is not intended to limit the scope of the present invention. Moreover, as the contents disclosed herein should be readily understood and can be implemented by a person skilled in the art, all equivalent changes or modifications which do not depart from the concept of the present invention should be encompassed by the appended claims.

What is claimed is:

1. A display device, comprising:
a display unit for displaying, inputting and outputting data; and
a back panel having at least one fixing unit, wherein the back panel covers a rear side of the display unit and the fixing unit extends outward from the back panel.

2. The display of claim 1, wherein the back panel and the fixing unit are integrally formed.

3. The display of claim 2, wherein the fixing unit has a first bent portion positioned perpendicular to the back panel at a border between the back panel and the fixing unit.

4. The display of claim 3, wherein the fixing unit has a second bent portion extended outward at a position adjacent to a front side of the display unit.

5. The display of claim 3, wherein the second bent portion is formed with a fastening hole.
